(19) United States
(12) Patent Application Publication
(10) Pub. No.: US 2009/0057907 A1
(43) Pub. Date: Mar. 5, 2009

(54) INTERCONNECTION STRUCTURE

(76) Inventors: Ming-Tzong Yang, Hsinchu County (TW); Tien-Chang Chang, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 11/847,335

(22) Filed: Aug. 30, 2007

(51) Int. Cl. H01L 23/52

(52) U.S. Cl. 257/760; 257/E23.141; 257/762

(57) ABSTRACT

An interconnection structure includes an inter-layer dielectric; a topmost copper metal layer inlaid into the inter-layer dielectric; an insulating layer disposed on the inter-layer dielectric and the topmost copper metal layer; a via opening in the insulating layer for exposing a top surface of the topmost copper metal layer, wherein the via opening consists of an inwardly tapered upper via portion and a lower via portion having a substantially vertical sidewall profile; and an aluminum layer filling into the via opening.

### BACKGROUND OF THE INVENTION

1. Field of the Invention

The invention relates to the field of semiconductor device and, more particularly, to a metal interconnection structure of a semiconductor chip capable of increasing the layout source of the semiconductor chip at the highest copper metal layer.

2. Description of the Prior Art

The reduction of the feature sizes of semiconductor devices using state-of-the-art semiconductor techniques have dramatically increased the device packing density of a single integrated circuit (IC) chip. However, as the device packing density increases, it is necessary to increase the number of electrical metal interconnect layers on the IC chip to effectively wire up the various devices on a substrate while reducing the chip size. For example, having two to six levels of metal interconnect layers in a single IC chip is a commonplace in this field.

FIG. 1 is a schematic, cross-sectional diagram illustrating an upper portion of a semiconductor chip 1 according to the prior art. The semiconductor chip 1 comprises a top metal layer 2 inlaid into an inter-layer dielectric 3. Typically, the top metal layer 2 is formed by conventional copper damascene methods and may serve as power planes. An insulating layer 4 is formed on the inter-layer dielectric 3 and has via opening 5 for exposing a top surface of the top metal layer 2.

In order to avoid the undesired oxidation of the exposed top surface of the top metal layer 2, an environment passivated metal such as an aluminum layer 6 is filled into the via opening 5 by sputtering methods. It is known in the art that the aluminum layer 6 may also be used to form a so-called re-distribution layer (RDL) above the insulating layer 4.

However, due to the poor step coverage during the sputtering of the aluminum layer 6, the via opening 5 with a dimension that is greater than 2.3 μm×2.3 μm (normally 4 μm×4 μm) is required to prevent void defect 7 from occurring within the via opening 5. Because the via opening 5 is large and not shrinkable for the aforesaid reason, the underlying top metal layer 2 thus occupies unnecessarily large surface area of the semiconductor chip.

One disadvantage is that the layout or routing source is reduced and constrained. It is desirable to increase the layout or routing source as much as possible, as the device packing density increases.

FIG. 2 illustrates one approach to the connection between RDL and the topmost copper metal layer according to the prior art. As shown in FIG. 2, tungsten (W) via plug 9 is employed to connect the RDL 6a and the topmost copper metal layer 2a. However, such interconnection structure cannot provide reliable performance in terms of electromagnetic interference shielding.

### SUMMARY OF THE INVENTION

It is one object of this invention to provide an improved interconnection structure between RDL and the topmost copper metal layer in order to solve the above-mentioned prior art problems.

According to the claimed invention, an interconnection structure between RDL and the topmost copper metal layer is provided. The interconnection structure includes an inter-layer dielectric; a topmost copper metal layer inlaid into the inter-layer dielectric; an insulating layer disposed on the inter-layer dielectric and the topmost copper metal layer; a via opening in the insulating layer for exposing a top surface of the topmost copper metal layer, wherein the via opening consists of an inwardly tapered upper via portion and a lower via portion having a substantially vertical sidewall profile; and an aluminum layer filling into the via opening.

These and other objectives of the invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a schematic, cross-sectional diagram illustrating an upper portion of a semiconductor chip according to the prior art;

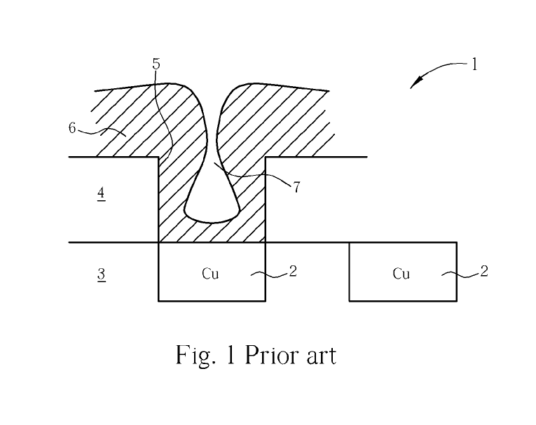

FIG. 2 is a schematic, cross-sectional diagram illustrating an interconnection structure between RDL and the topmost copper metal layer according to the prior art; and

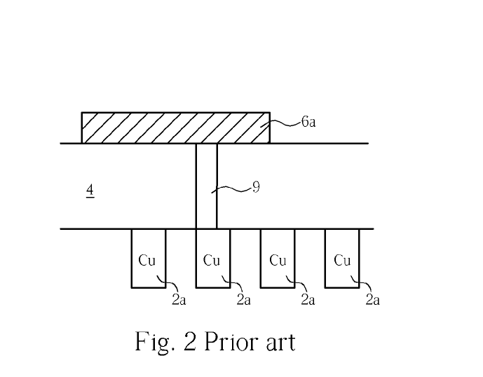

FIG. 3 is a schematic, cross-sectional diagram illustrating an upper portion of a semiconductor chip according to one preferred embodiment of this invention.

### DETAILED DESCRIPTION

The invention pertains to a unitary interconnection structure between RDL and the topmost copper metal layer.

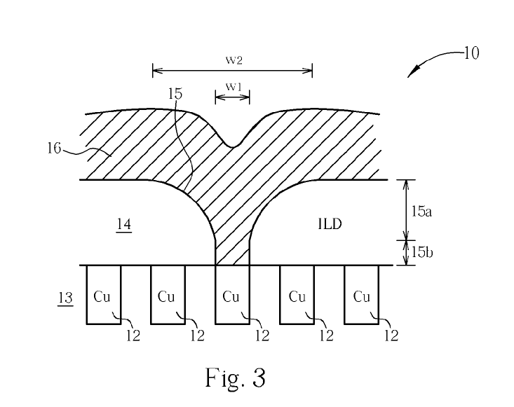

Please refer to FIG. 3. FIG. 3 is a schematic, cross-sectional diagram illustrating an upper portion of a semiconductor chip 10, which is germane to this invention, in accordance with one preferred embodiment of this invention. The semiconductor chip 10 comprises a topmost copper metal layer 12 inlaid into an inter-layer dielectric 13. The topmost copper metal layer 12 is formed by conventional copper damascene methods and may serve as power planes.

As known in the art, the copper damascene methods provide a solution to form a conductive wire coupled with an integral via plug without the need of dry etching copper. Either a single damascene or a dual damascene structure may be used to connect devices and/or wires of an integrated circuit.

Generally, the dual damascene process encompasses trench-first, via-first, partial-via-first and self-aligned processes. By way of example, one conventional method of fabricating a dual damascene structure is to etch dielectric layers to form a trench and a via hole. The via hole and the trench are lined with barrier such as Titanium (Ti) or Titanium Nitride (TiN) and then filled with copper. A planarization process such as CMP is then performed to form the damascened metal interconnects.

According to this invention, the semiconductor chip 10 may have, for example, a 1P5M scheme (i.e., one polysilicon layer and five copper metal interconnection layers) or 1P6M scheme wherein merely the topmost copper metal layer 12 is illustrated. For the sake of simplicity, the substrate, the devices fabricated on the substrate and the lower levels of copper metal interconnection are omitted.

The inter-layer dielectric 13 may comprise silicon oxide, silicon nitride, silicon carbide, silicon oxy-nitride or low-k or ultra low-k materials such as organic (e.g., SiLK) or inorganic (e.g., HSQ).

An insulating layer 14 is formed on the inter-layer dielectric 13 and has at least one via opening 15 for exposing a top surface of the underlying top metal layer 12. According to the preferred embodiment of this invention, the insulating layer 14 may be silicon oxide, silicon nitride, silicon carbide, silicon oxy-nitride, polyimide or the like. According to the preferred embodiment of this invention, the insulating layer 14 has a thickness of about 6000 angstroms to 9000 angstroms, preferably 8000 angstroms.

As specifically indicated in FIG. 3, the via opening 15 is generally divided into two portions: an inwardly tapered upper via portion 15a and a lower via portion 15b. The lower via portion 15b of the via opening 15 has a steep (or substantially vertical) sidewall profile and a critical dimension W₁ at its bottom of about 0.5 μm or less. The via opening 15 can be formed by two-stage etching methods involving the use of isotropic and anisotropic etch recipes.

Preferably, the height of the lower via portion 15b is about ½ to ⅕ of the thickness of the insulating layer 14, but not limited thereto. Preferably, the width W₂ at the top of the inwardly tapered upper via portion 15a ranges between 0.6 μm and 1.0 μm.

The inwardly tapered upper via portion 15a of the via opening 15 facilitates the filling of the aluminum layer 16 into the via opening 15 and avoids void formation in the via opening 15.

Since the via opening 15 has relatively smaller critical dimension at its bottom, the dimension of the underlying topmost copper metal layer 12 can be shrunk to about 0.5 μm corresponding to the critical dimension WI at the bottom of the lower via portion 15b. This significantly increases the layout or routing source of the semiconductor chip at the highest level of copper metal interconnection.

As specifically indicated in FIG. 3, the line width of each of the damascened copper metal layers 12 is decreased compared to the prior art structure. Another advantage of this invention is that one level of copper metal layer may be spared because the aluminum layer 16 alone can constitute a re-distribution layer. The aluminum layer 16 may be patterned into power or ground lines to substitute a copper metal layer.

Those skilled in the art will readily observe that numerous modifications and alterations of the device and method may be made while retaining the teachings of the invention.

1. An interconnection structure comprising:
an inter-layer dielectric;
a topmost copper metal layer inlaid into said inter-layer dielectric;
an insulating layer disposed on said inter-layer dielectric and said topmost copper metal layer;
a via opening in said insulating layer for exposing a top surface of said topmost copper metal layer, wherein said via opening consists of an inwardly tapered upper via portion and a lower via portion having a substantially vertical sidewall profile; and
a re-distribution layer comprising aluminum filling into said via opening.

2. The interconnection structure according to claim 1, wherein said re-distribution layer is patterned into a power/ground line.

3. The interconnection structure according to claim 1 wherein said lower via portion has a critical dimension W₁ at its bottom of about 0.5 μm or less.

4. The interconnection structure according to claim 1 wherein a width W2 at the top of said inwardly tapered upper via portion ranges between 0.6 μm and 1.0 μm.

5. The interconnection structure according to claim 1 wherein said insulating layer comprises silicon oxide, silicon nitride, silicon carbide, silicon oxy-nitride and polyimide.

6. The interconnection structure according to claim 1 wherein said insulating layer has a thickness of about 6000 angstroms to 9000 angstroms.

7. The interconnection structure according to claim 1 wherein said inter-layer dielectric comprise silicon oxide, silicon nitride, silicon carbide, silicon oxy-nitride, low-k and ultra low-k materials.

8. The interconnection structure according to claim 1 wherein a height of said lower via portion is about ½ to ⅕ of a thickness of said insulating layer.

9. The interconnection structure according to claim 1 wherein said topmost copper metal layer is the fifth level copper metal of a semiconductor chip with a 1P5M scheme.

10. The interconnection structure according to claim 1 wherein said topmost copper metal layer is the sixth level copper metal of a semiconductor chip with a 1P6M scheme.

11. An interconnection structure comprising:
an inter-layer dielectric;
a topmost copper metal layer inlaid into said inter-layer dielectric;
an insulating layer disposed on said inter-layer dielectric and said topmost copper metal layer;
a via opening in said insulating layer for exposing a top surface of said topmost copper metal layer, wherein said via opening consists of an inwardly tapered upper via portion and a lower via portion having a substantially vertical sidewall profile; and
a re-distribution layer comprising an aluminum via structure integrally formed with said re-distribution layer, wherein said aluminum via structure is formed in said via opening.
